(19) United States
(12) Patent Application Publication
(10) Pub. No.: US 2008/0083982 A1
(43) Pub. Date: Apr. 10, 2008

(54) METHOD AND SYSTEM FOR INITIATING PROXIMITY WARNING ALARM FOR ELECTRONIC DEVICES AND PROHIBITING OPERATION THEREOF

(75) Inventors: Edward E. Kelley, Wappingers Falls, NY (US); Wayne M. Delia, Poughkeepsie, NY (US); Franco Motika, Hopewell Junction, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/548,031

(22) Filed: Oct. 10, 2006

(51) Int. Cl. H01L 23/34

(52) U.S. Cl. 257/722

(57) ABSTRACT

A system for tracking the location of electronic devices and prohibiting unauthorized operation thereof includes a control unit, configured for wireless communication with an electronic device, the electronic device having a basic input/output system (BIOS) associated therewith. The control unit is configured to remotely disable the electronic device in the event the electronic device is detected to be beyond a programmed radius for a programmed duration, in accordance with a specifically defined level of security, wherein the extent to which the electronic device is disabled by the control unit is dependent upon the specifically defined level of security.

### BACKGROUND

The present invention relates generally to wireless tracking of personal devices, and, more particularly, to method and system for initiating a proximity warning alarm for electronic devices and subsequently prohibiting the unauthorized operation thereof.

It is commonplace for personal items, such as cellular telephones, car keys, personal digital assistants (PDAs), etc. to become lost or misplaced. In the case of more expensive electronic items, such as digital cameras and notebook computers, there is also the issue of vulnerability of these items to unauthorized use, as well as the possibility of sensitive information therein being accessible by third parties.

Presently, there are tracking and alert systems in existence that send an alarm signal to a user whenever a sensed item becomes separated from an owner beyond a certain range. For example, an item such as a cell phone may be outfitted with a remote sensor such that when the phone becomes separated from an alert (processing) device beyond a predetermined distance and/or for a predetermined amount of time, the sensor notifies the processing device. In turn, the processing device alerts the owner of the impending separation by means of a signal such as an audio alarm, a blinking light, a text message, a phone call, pager signal, etc.

However, this alert function by itself does not prevent a theft of an item nor does it necessarily prohibit the unauthorized use of such items, including access to sensitive data that may be stored therein. Certain other systems, such as those preventing unauthorized use of devices like cellular telephones, provide a “disabling” feature that prevents a third party from operating the phone if the phone becomes separated by more than a predetermined distance from a user. Even with such upgraded protections, this may not necessarily prevent a resourceful third party from hacking into the device so as to gain access to sensitive information.

Accordingly, it would be desirable to devise an effective way to implement both a loss of proximity warning for an electronic device, as well as to provide a selectable level of disablement of the device to prevent unauthorized access to sensitive data therein.

### SUMMARY

The foregoing discussed drawbacks and deficiencies of the prior art are overcome or alleviated by, in an exemplary embodiment, a system for tracking the location of electronic devices and prohibiting unauthorized operation thereof, including: a control unit, configured for wireless communication with an electronic device, the electronic device having a basic input/output system (BIOS) associated therewith; the control unit configured to remotely disable the electronic device in the event the electronic device is detected to be beyond a programmed radius for a programmed duration, in accordance with a specifically defined level of security; wherein the extent to which the electronic device is disabled by the control unit is dependent upon the specifically defined level of security.

In another embodiment, a method for tracking the location of electronic devices and prohibiting unauthorized operation thereof includes programming a control unit to remotely disable an electronic device in wireless communication therewith, in the event the electronic device is detected to be beyond a programmed radius for a programmed duration, in accordance with a specifically defined level of security, the electronic device having a basic input/output system (BIOS) associated therewith; wherein the extent to which the electronic device is disabled by the control unit is dependent upon the specifically defined level of security.

### BRIEF DESCRIPTION OF THE DRAWINGS

Referring to the exemplary drawings wherein like elements are numbered alike in the several Figures:

FIG. 1 is a schematic diagram of an exemplary proximity warning system for electronic devices, suitable for use in accordance with an embodiment of the invention;

FIG. 2 is a more detailed view of an exemplary electronic device used in the proximity warning system of FIG. 1;

FIG. 3 is table illustrating an exemplary set of security levels and associated disable/restore actions corresponding to the security levels that may be used in the proximity warning system, in accordance with an embodiment of the invention; and

FIG. 4 is a flow diagram illustrating a method for initiating a proximity warning alarm for electronic devices and subsequently prohibiting the unauthorized operation thereof, in accordance with an embodiment of the invention.

### DETAILED DESCRIPTION

Disclosed herein is a method and system of initiating a proximity warning alarm for electronic devices and subsequently prohibiting the unauthorized operation thereof. Briefly stated, a programmable proximity warning system for personal electronic devices provides a plurality of security levels, which in turn determines a degree of functional disablement of the electronic device in the event that certain programmed proximity/time conditions are satisfied. Generally speaking, the protected devices can be rendered temporarily disabled to permanently disabled, depending on the level of security programmed into the system. In the case of temporarily disabled devices, the complexity of initiating a suitable procedure for re-enabling the device may vary, again depending upon the level(s) of security programmed for the particular device. As described in more detail herein, examples of temporary disablement may include activities such as: encryption of a basic input/output system (BIOS) of a device; overwriting of the code of the BIOS; and blowing of electrically programmable fuses within the devices so as to render certain data paths inoperable (but restorable). Further, an example of permanent disablement may include blowing of enough electrically programmable fuses within the devices so as to render certain data paths inoperable and not restorable.

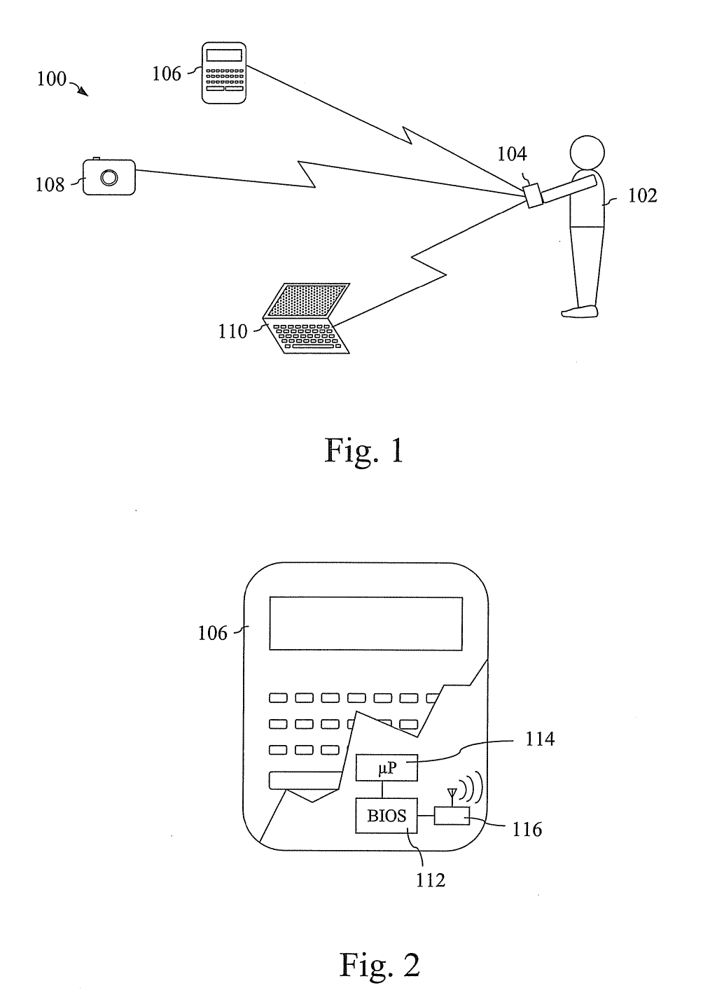

Referring initially to FIG. 1, there is shown an exemplary proximity warning system 100 for electronic devices suitable for use in accordance with an embodiment of the invention. A user 102 (e.g., owner of one or more electronic devices to be tracked) has an control unit 104, which is configured for wireless communication with various electronic devices such as, for example, personal digital assistant (PDA) 106, digital camera 108 and notebook computer 110. It will be appreciated that other types of electronic devices may also be utilized in the proximity warning system 100, particularly where such devices are relatively expensive and/or contain sensitive information stored thereon.

In an exemplary embodiment, each of the electronic devices utilized within the system 100 includes a transmitting/receiving device capable of communicating (directly or indirectly) its proximity to the control unit. In terms of proximity sensing, the electronic devices (106, 108, 110, etc.) may have this capability integrated therein or be provided with separate, attachable sensing devices for communication with the control unit 104. The particular manner of communication proximity information between the control unit 104 and the electronic devices may be in accordance with techniques known in the art, such as through global position satellite (GPS) tracking, strength of signal received from the devices, etc.

As in the case of certain conventional tracking systems, the electronic devices (106, 108, 110, etc.) may have the capability of transmitting and thus activating one or more alarm indicators (e.g., audible alarm, indicator light, text display) on the control unit 104 when the device is no longer within the programmed proximity with respect to the control unit 104. Furthermore, the control unit 104 can also be configured to transmit a signal to activate one or more alarm indicators on the electronic devices themselves, whenever the devices are no longer within the programmed proximity and/or whenever a device ceases to send proximity signals back to the control unit 104. However, in the event of a theft of an electronic device (as opposed to the user simply misplacing the device), the device will likely continue to move away from the location of user/control unit and, as such, a disabling function is desired in order to prevent unauthorized persons from operating the device.

As further illustrated by the exemplary PDA device 106 shown in FIG. 2, each monitored electronic device includes a basic input/output system (BIOS) 112 which refers to the built-in software or code utilized by a processor 114 of the device when first powered on, without first accessing other software programs stored on various storage media (e.g., hard drives, floppies, and CDs). The primary function of a BIOS is to prepare the machine so other software programs stored on various media can load, execute, and assume control of the device. This process is also referred to as “booting up.” On a personal computer, for example, the BIOS contains all of the code needed to control the keyboard, display screeen, disk drives, serial communications, and other miscellaneous functions.

BIOS is sometimes called firmware, which is software that is embedded in a hardware device. Earlier BIOSes were formed on ROM chips that could not be altered. However, as their complexity and need for updates grew, BIOS firmware was stored on EEPROM or flash memory devices. In the exemplary system 100, the BIOS 112 is formed in a chip having electrically programmable capabilities, such as “eFuse” technology developed by IBM. This technology utilizes a combination of unique software algorithms and microscopic electrical fuses to help chips regulate and adapt to changing conditions and system demands by adjusting their circuitry. Particularly, an eFuse device may be programmed by passing a sufficient current through the structure such that its resistance is significantly altered from its initially fabricated state. Thus, upon receipt of an appropriate control signal at a transmitter/receiver device 116 included within the tracked electronic device, the BIOS may be disabled in a manner that corresponds to a specific level of programmed security.

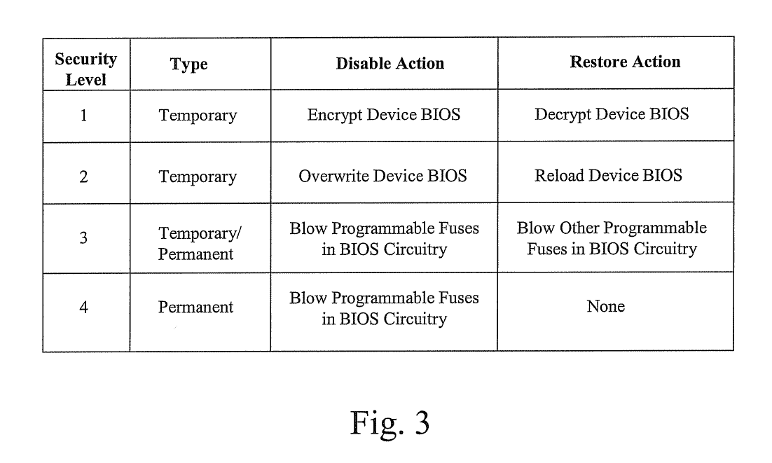

FIG. 3 is table illustrating an exemplary set of security levels and associated disable/restore actions corresponding to the security levels that may be used in the proximity warning system, in accordance with an embodiment of the invention. Depending on the manner in which the device is disabled in the event of a loss of proximity, there may or may not be a means of reactivating the device upon successful recovery of the same. For instance, a first level (Level 1) of security provides for encryption of the device BIOS. Upon satisfaction of the programmed proximity conditions for Level 1 security, the control unit 104 may transmit an encryption key stored in the device bios, which is then used to encrypt the operating system and data stored on the device. After encryption, the encryption key is erased from the device. This level would be considered a temporary mode of device disablement, in that the encryption key can be subsequently sent from the control unit to the device (upon device recovery) to decrypt the device operating system and data stored on the device.

A second level (Level 2) of disablement is presented in FIG. 3, in which the specific disable action initiated is the actual overwriting of the operating system and stored data with (for example), stored zeroes. In other words, the operating system and stored data are effectively erased from the device. This type of disablement is also temporary, in that the functionality of the device can be restored. However, instead of a relatively simple operation of transmitting a key from the control unit, restoration from a Level 2 disablement would involve reloading the operating system and stored data from another storage device (e.g., a database) where such information was previously stored. For example, the control unit 104 may serve as such a device.

Further, a third level (Level 3) of disablement is available, in which electrically programmable fuse devices (e.g., eFuse devices discussed above) are blown in the device circuitry so as to physically sever certain circuit paths. In this instance, functionality may be restored by blowing other fuses so as to restore and/or create alternate circuit paths within the device. As such, this type of disablement is temporary to a limited extent, in that after a certain amount of disablement cycles where more and more fuses have been blown, there will come a point in time when the device functionality can no longer be restored. Conceivably, however, such a security measure could be implemented through the used of phase change material (PCM) fuse devices, in which the resistivity of the PCM can be repeatedly programmed from a low resistance to a high resistance state, and vice versa.

As also shown in FIG. 3, fourth level (Level 4) of disablement is provided, in which the disabling action is (like Level 3) the blowing of programmable fuses. However, in contrast to Level 3, a disablement action under security Level 4 results in a sufficient number and location of fuses blown such that the device is rendered permanently inoperable and not restorable.

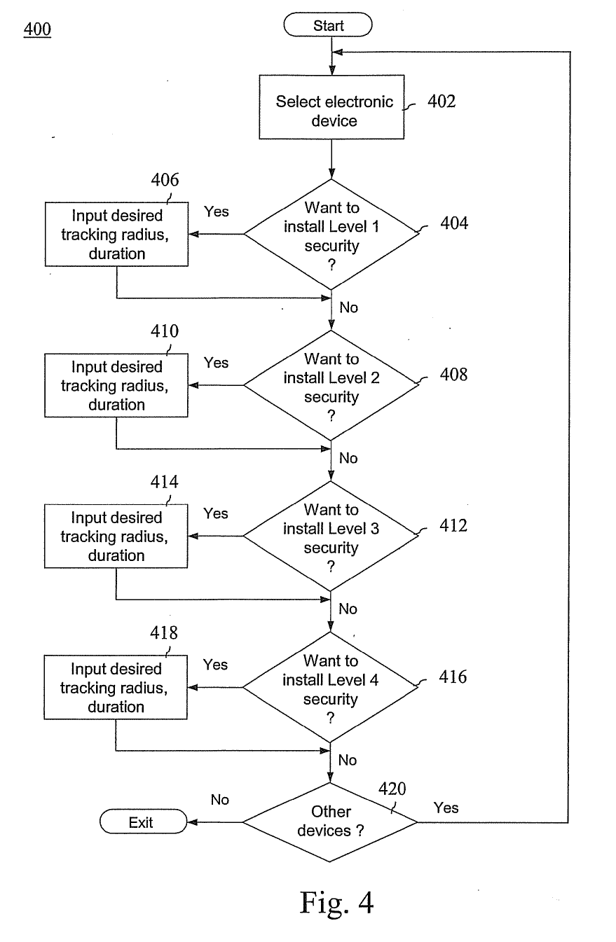

FIG. 4 is a flow diagram illustrating a method 400 for initiating a proximity warning alarm for electronic devices and subsequently prohibiting the unauthorized operation thereof, in accordance with an embodiment of the invention. Beginning at block 402, an electronic device to be monitored is selected. The device selection may be facilitated using, for example, the control unit 104 of FIG. 1. For the device selected, it is then determined at decision block 404 whether Level 1 security is desired. If so, the desired tracking radius is inputted into the control system (shown in block 406), beyond which a Level 1 disablement of the device will occur. In addition to the tracking radius, an associated duration may also be input, which corresponds to an amount of time elapsed for the device to beyond the set radius before the disablement is interrupted.

Regardless of whether a Level 1 security mode is set for the device, the method 400 then proceeds to block 408 to see whether Level 2 security for the selected device is desired. If so, the desired tracking parameters (e.g., radius and duration) are inputted into the control system (shown in block 410), beyond which a Level 2 disablement of the device will occur. Then, it is determined at decision block 412 whether Level 3 security is desired. Again, if Level 3 security is desired, the desired tracking radius and associated duration are inputted into the control system (shown in block 414), beyond which a Level 3 disablement of the device will occur. Finally, it is determined at decision block 416 whether Level 4 security is desired. If Level 4 security is desired, the desired tracking radius and associated duration are inputted into the control system (shown in block 418), beyond which a Level 4 (permanent) disablement of the device will occur. Upon completion of proximity tracking programming of the selected device, if other devices are desired to be programmed as indicated in decision block 420, the method returns to block 402, otherwise it exits at that point.

As will be appreciated, the system may be programmed such that one or more of the programmed disablement actions may take place as a tracked device becomes further separated from the owner, or an additional amount of time passes. For instance, when beyond a threshold control radius, a device may be initially disabled by Level 1 security (e.g., encryption) after a first amount of time has passed. Then, if the device has not been recovered by an additional amount of time, the device may be further disabled by Level 2 security (e.g., BIOS erasure). Naturally, this sequence may further progress through a longer duration and/or distance up until the device is ultimately rendered permanently disabled.

In view of the above, the present method embodiments may therefore take the form of computer or controller implemented processes and apparatuses for practicing those processes. The disclosure can also be embodied in the form of computer program code containing instructions embodied in tangible media, such as floppy diskettes, CD-ROMs, hard drives, or any other computer-readable storage medium, wherein, when the computer program code is loaded into and executed by a computer or controller, the computer becomes an apparatus for practicing the invention.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A system for tracking the location of electronic devices and prohibiting unauthorized operation thereof, comprising:
a control unit, configured for wireless communication with an electronic device, the electronic device having a basic input/output system (BIOS) associated therewith;
the control unit configured to remotely disable the electronic device in the event the electronic device is detected to be beyond a programmed radius for a programmed duration, in accordance with a specifically defined level of security;
wherein the extent to which the electronic device is disabled by the control unit is dependent upon the specifically defined level of security.

2. The system of claim 1, wherein the control unit is configured for both temporary disablement and permanent disablement of the electronic device.

3. The system of claim 2, wherein:
the control unit is configured for a first level of security in which the electronic device is temporarily disabled by encryption of the device BIOS and data stored thereon;
the control unit is configured for a second level of security in which the electronic device is temporarily disabled by overwriting of the device BIOS and data stored thereon;
the control unit is configured for a third level of security in which the electronic device is disabled by blowing of selected electrically programmable fuses of the device BIOS and circuitry therein, wherein operation of the electronic device is capable of being restored at least once after disablement thereof, and
the control unit is configured for a fourth level of security in which the electronic device is permanently disabled by blowing of selected electrically programmable fuses of the device BIOS and circuitry therein.

4. The system of claim 3, wherein the control unit is further configured to restore operation of the electronic device disabled in accordance with the first level of security by transmission of an encryption key thereto.

5. The system of claim 3, wherein the control unit is further configured to restore operation of the electronic device disabled in accordance with the second level of security by reloading the device BIOS and data stored thereon from a stored location.

6. The system of claim 3, wherein the control unit is further configured to operation of the electronic device disabled in accordance with the third level of security by blowing of additionally selected electrically programmable fuses of the device BIOS and circuitry therein.

7. The system of claim 3, wherein the electronic device is configured for disablement according to one of the levels of security, notwithstanding a previous disablement executed according to another of the levels of security immediately prior thereto.

8. The system of claim 3, wherein the control unit is configured to transmit a signal to activate one or more alarm indicators on the electronic device whenever the device is no longer within the programmed proximity and/or whenever the electronic device ceases to send proximity signals back to the control unit.

9. A method for tracking the location of electronic devices and prohibiting unauthorized operation thereof, the method comprising:
programming a control unit to remotely disable an electronic device in wireless communication therewith, in the event the electronic device is detected to be beyond a programmed radius for a programmed duration, in accordance with a specifically defined level of security, the electronic device having a basic input/output system (BIOS) associated therewith;
wherein the extent to which the electronic device is disabled by the control unit is dependent upon the specifically defined level of security.

10. The method of claim 9, wherein the control unit is configured for both temporary disablement and permanent disablement of the electronic device.

11. The method of claim 10, further comprising:
inputting a first set of tracking parameters into the control unit so as to implement a first level of security in which the electronic device is temporarily disabled by encryption of the device BIOS and data stored thereon;
inputting a second set of tracking parameters into the control unit so as to implement a second level of security in which the electronic device is temporarily disabled by overwriting of the device BIOS and data stored thereon;
inputting a third set of tracking parameters into the control unit so as to implement a third level of security in which the electronic device is disabled by blowing of selected electrically programmable fuses of the device BIOS and circuitry therein, wherein operation of the electronic device is capable of being restored at least once after disablement thereof, and
inputting a fourth set of tracking parameters into the control unit so as to implement a fourth level of security in which the electronic device is permanently disabled by blowing of selected electrically programmable fuses of the device BIOS and circuitry therein.

12. The method of claim 11, wherein the control unit is further configured to restore operation of the electronic device disabled in accordance with the first level of security by transmission of an encryption key thereto.

13. The method of claim 11, wherein the control unit is further configured to restore operation of the electronic device disabled in accordance with the second level of security by reloading the device BIOS and data stored thereon from a stored location.

14. The method of claim 11, wherein the control unit is further configured to operation of the electronic device disabled in accordance with the third level of security by blowing of additionally selected electrically programmable fuses of the device BIOS and circuitry therein.

15. The method of claim 11, wherein the electronic device is configured for disablement according to one of the levels of security, notwithstanding a previous disablement executed according to another of the levels of security immediately prior thereto.

16. The method of claim 11, further comprising transmitting a signal from the control unit to activate one or more alarm indicators on the electronic device whenever the device is no longer within the programmed proximity and/or whenever the electronic device ceases to send proximity signals back to the control unit.
